(19) United States
(12) Patent Application Publication
(10) Pub. No.: US 2024/0363812 A1
(43) Pub. Date: Oct. 31, 2024

(54) LIGHT-EMITTING DEVICE

(71) Applicant: NICHIA CORPORATION, Anan-shi (JP)

(72) Inventors: Tatsuya HAYASHI, Tokushima-shi (JP); Shinya OKURA, Tokushima-shi (JP)

(21) Appl. No.: 18/637,232

(22) Filed: Apr. 16, 2024

(30) Foreign Application Priority Data
Apr. 27, 2023 (JP) 2023-073321
Feb. 8, 2024 (JP) 2024-018079

(51) Int. Cl. H01L 33/50; H01L 25/075; H01L 33/52; H01L 33/62

(52) U.S. Cl. CPC H01L 33/504; H01L 25/0753; H01L 33/52; H01L 33/62

(57) ABSTRACT

A light-emitting device includes a light-emitting element, a wavelength conversion layer, and a light-transmissive layer. The light-emitting element has a light exit surface. The wavelength conversion layer has a lower surface and an upper surface. The wavelength conversion layer is disposed on or above the light-emitting element so that the lower surface of the wavelength conversion layer faces the light exit surface of the light-emitting element. The wavelength conversion layer includes a first layer and a second layer. The first layer contains a first phosphor particle, and constitutes a part of the upper surface and a part of the lower surface of the wavelength conversion layer. The second layer contains a second phosphor particle and a light-reflective particle, and constitutes a part of the upper surface and a part of the lower surface of the wavelength conversion layer. The light-transmissive layer is disposed on or above the wavelength conversion layer.

### CROSS-REFERENCE TO RELATED APPLICATION

This application claims priority to Japanese Patent Application No. 2023-073321 filed on Apr. 27, 2023, and Japanese Patent Application No. 2024-018079 filed on Feb. 8, 2024, the disclosures of which are hereby incorporated herein by reference in their entireties.

### TECHNICAL FIELD

The present disclosure relates to a light-emitting device.

### BACKGROUND

LEDs are used as light sources for vehicle lamps such as headlights in recent years. For example, Japanese Patent Publication No. 2017-011259 discloses a light-emitting device having a light distribution suitable for headlights because of the combination of a plurality of light-emitting elements having different emission surface areas.

### SUMMARY

An object of the present disclosure is to provide a light-emitting device having a high-luminance region and a low-luminance region in an emission surface.

A light-emitting device according to an embodiment of the present disclosure includes a light-emitting element, a wavelength conversion layer, and a light-transmissive layer. The light-emitting element has a light exit surface. The wavelength conversion layer has a lower surface and an upper surface opposite to the lower surface. The wavelength conversion layer is disposed on or above the light-emitting element so that the lower surface of the wavelength conversion layer faces the light exit surface of the light-emitting element. The wavelength conversion layer includes a first layer and a second layer. The first layer contains a first phosphor particle, and constitutes a part of the upper surface and a part of the lower surface of the wavelength conversion layer. The second layer contains a second phosphor particle and a light-reflective particle, and constitutes a part of the upper surface and a part of the lower surface of the wavelength conversion layer. The light-transmissive layer is disposed on or above the wavelength conversion layer.

According to embodiments of the present disclosure, a light-emitting device having a high-luminance region and a low-luminance region in an emission surface can be provided.

### BRIEF DESCRIPTION OF THE DRAWINGS

FIG. 1 is a schematic perspective view of a light-emitting device according to a first embodiment.

FIG. 2 is a schematic plan view of the light-emitting device according to the first embodiment.

FIG. 3A is a schematic cross-sectional view of the light-emitting device taken along the line A-A of FIG. 2.

FIG. 3B is a schematic cross-sectional view of a variation of the light-emitting device taken along the line A-A of FIG. 2.

FIG. 4A is a schematic plan view showing an example of a step in a method of manufacturing the light-emitting device according to the first embodiment.

FIG. 4B is a schematic cross-sectional view taken along the line B-B of FIG. 4A.

FIG. 5A is a schematic plan view showing an example of a step in the method of manufacturing the light-emitting device according to the first embodiment.

FIG. 5B is a schematic cross-sectional view taken along the line C-C of FIG. 5A.

FIG. 6A is a schematic plan view showing an example of a step in the method of manufacturing the light-emitting device according to the first embodiment.

FIG. 6B is a schematic cross-sectional view taken along the line D-D of FIG. 6A.

FIG. 7A is a schematic plan view showing an example of a step in the method of manufacturing the light-emitting device according to the first embodiment.

FIG. 7B is a schematic cross-sectional view taken along the line E-E of FIG. 7A.

FIG. 8 is a schematic cross-sectional view showing an example of a step in the method of manufacturing the light-emitting device according to the first embodiment.

FIG. 9 is a schematic cross-sectional view showing an example of a step in the method of manufacturing the light-emitting device according to the first embodiment.

FIG. 10 is a schematic cross-sectional view showing an example of a step in the method of manufacturing the light-emitting device according to the first embodiment.

FIG. 11 is a schematic cross-sectional view showing an example of a step in the method of manufacturing the light-emitting device according to the first embodiment.

FIG. 12 is a schematic perspective view of a light-emitting device according to a second embodiment.

FIG. 13 is a schematic plan view of the light-emitting device according to the second embodiment.

FIG. 14 is a schematic cross-sectional view taken along the line F-F of FIG. 13.

FIG. 15 is a schematic plan view of a light-emitting element 2 of the light-emitting device according to the second embodiment.

FIG. 16 is a schematic plan view of a wiring board 50 of the light-emitting device according to the second embodiment.

FIG. 17 is a schematic perspective view of a light-emitting device according to a third embodiment.

FIG. 18 is a schematic cross-sectional view of the light-emitting device according to the third embodiment.

### DETAILED DESCRIPTIONS

Certain embodiments of the present disclosure are described below with reference to the accompanying drawings. The embodiments described below are not limiting but are intended to exemplify light-emitting devices and methods of manufacturing the light-emitting devices to give a concrete form to the technical idea of the present embodiments. Unless specifically stated otherwise, descriptions of the sizes, materials, shapes, and relative positions of constituent components in the embodiments are not intended to limit the scope of the present invention to those descriptions, but are rather only examples. Sizes or positional relationships of components illustrated in the drawings may be exaggerated or simplified in order to clarify the descriptions. The illustration of components may be partly omitted to prevent the drawings from being excessively complicated, and end views showing only cross sections of members may be used as cross-sectional views. The term “cover” and the terms related thereto include not only being in direct contact, but also include indirect covering, such as covering with another member interposed therebetween. The term “dispose” the term related thereto includes not only disposition in direct contact but also includes indirect disposition, such as disposition with another member therebetween. The term “schematic plan view” as used in the present specification refers to a drawing from the emission surface side of the light-emitting device.

A light-emitting device according to an embodiment of the present disclosure includes a light-emitting element having a light exit surface, and a wavelength conversion layer that has a lower surface and an upper surface opposite to the lower surface and is disposed on or above the light-emitting element so that the lower surface of the wavelength conversion layer faces the light exit surface of the light-emitting element. The wavelength conversion layer includes a first layer containing first phosphor particles and a second layer containing second phosphor particles and light-reflective particles. The upper surface and the lower surface of the wavelength conversion layer include the first layer and the second layer.

The light-emitting device having the structure as described above can emit lights of different luminances from the upper surface of the wavelength conversion layer because the upper surface and the lower surface of the wavelength conversion layer include the first layer containing the first phosphor particles and the second layer containing the second phosphor particles and the light-reflective particles.

That is, as will be described below in detail, on the basis of the type, content, and the like of the first phosphor particles contained in the first layer and the types, contents, and the like of the second phosphor particles and the light-reflective particles contained in the second layer, light of different luminances can be emitted from the upper surface of the first layer and the upper surface of the second layer in the upper surface of the wavelength conversion layer.

Unless specifically stated otherwise, in the present specification, the upper surface refers to a surface on the side on which a main part of light of the light-emitting device is emitted, and the lower surface refers to a surface opposite to the upper surface.

Further, on the basis of the type, content, and the like of the first phosphor particles contained in the first layer and the types, contents, and the like of the second phosphor particles and the light-reflective particles contained in the second layer, the light-emitting device of the embodiment can emit light of different emission spectra from the upper surface of the first layer and the upper surface of the second layer in the upper surface of the wavelength conversion layer.

Embodiments will be described below referring to examples of specific structures of the light-emitting device in the present disclosure.

### First Embodiment

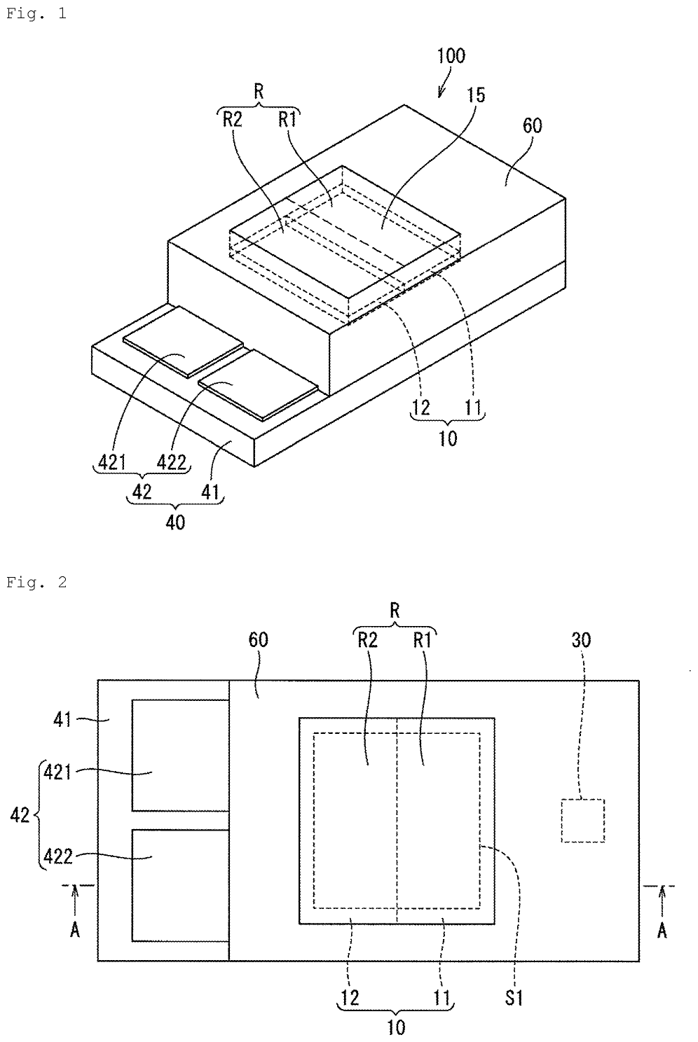

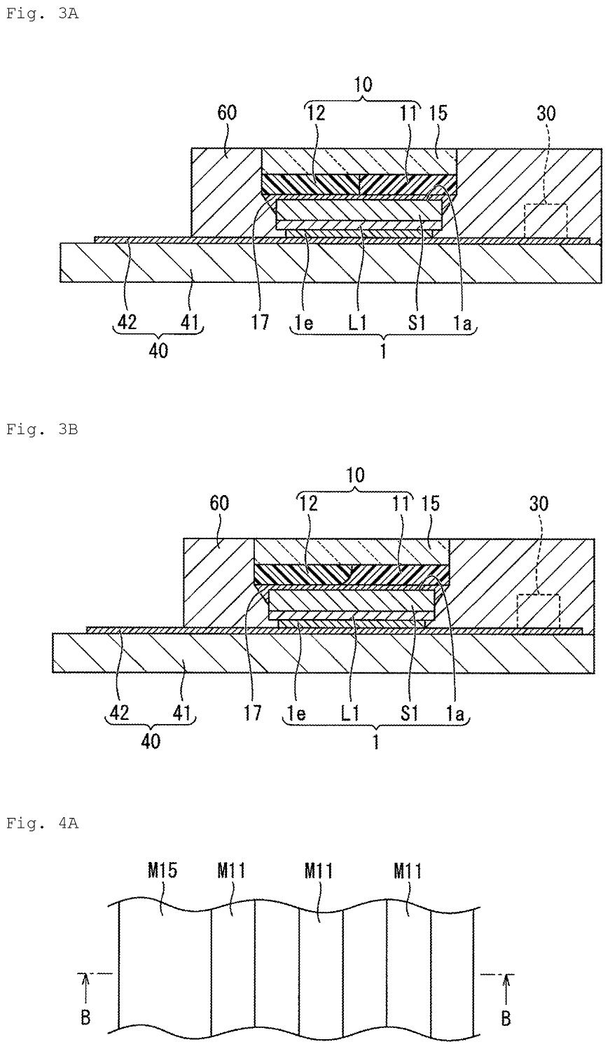

FIG. 1 is a schematic perspective view of a light-emitting device according to a first embodiment. FIG. 2 is a schematic plan view of the light-emitting device according to the first embodiment from above. FIG. 3A is a schematic cross-sectional view taken along the line A-A of FIG. 2.

As shown in FIG. 3A and other drawings, the light-emitting device according to the first embodiment includes a wiring board 40, a light-emitting element 1 disposed on the wiring board 40, and a wavelength conversion layer 10 disposed on or above the light-emitting element 1. The wavelength conversion layer 10 has a lower surface and an upper surface opposite to the lower surface and is disposed on or above the light-emitting element 1 such that the lower surface faces a light exit surface 1a of the light-emitting element. In the light-emitting device of the first embodiment, the lower surface of the wavelength conversion layer 10 is bonded to the light exit surface 1a of the light-emitting element using a light-transmissive bonding member 17. A light-transmissive member 15 is disposed on or above the upper surface of the wavelength conversion layer 10. Further, on the wiring board 40, except for the upper surface of the light-transmissive member 15 (the light exit surface of the light-emitting device 100), lateral surfaces of the light-emitting element 1, the wavelength conversion layer 10, and the light-transmissive member 15 are covered with a covering member 60.

In the light-emitting device 100 of the first embodiment, the wavelength conversion layer 10 includes a first layer 11 containing the first phosphor particles and a second layer 12 containing the second phosphor particles and the light-reflective particles, and each of the upper surface and the lower surface of the wavelength conversion layer 10 is constituted by both the first layer 11 and the second layer 12. That is, the lower surface of the wavelength conversion layer 10 includes the lower surface (hereinafter may be referred to as a first lower surface) of the first layer 11 and the lower surface (hereinafter may be referred to as a second lower surface) of the second layer 12, the first lower surface and the second lower surface each face the light exit surface 1a of the light-emitting element 1, and light from the light-emitting element 1 enters the first layer 11 and the second layer 12 through the first lower surface and the second lower surface, respectively. The upper surface of the wavelength conversion layer 10 includes the upper surface (hereinafter may be referred to as a first upper surface) of the first layer 11 and the upper surface (hereinafter may be referred to as a second upper surface) of the second layer 12, and lights whose wavelengths have been converted respectively in the first layer 11 and the second layer 12 are emitted from the first upper surface and the second upper surface. The lights emitted from the first upper surface and the second upper surface are respectively emitted from a first light-emitting region R1 and a second light-emitting region R2, each of which is a portion of the upper surface of the light-transmissive member 15 (that is, a light-emitting region R of the light-emitting device 100).

The lights emitted from the first light-emitting region R1 and the second light-emitting region R2 can have respective luminances based on the type, content, and the like of the first phosphor particles contained in the first layer and the types, contents, and the like of the second phosphor particles and the light-reflective particles contained in the second layer. This structure allows for emission of lights of different luminances from the first light-emitting region R1 and the second light-emitting region R2.

For example, the wavelength of a portion of light from the light-emitting element 1 entering the first layer 11 through the first lower surface is converted by the first phosphor particles contained in the first layer to provide first converted light, and another portion of the light of the light-emitting element 1 is emitted from the first upper surface without being converted. The first converted light and the light from the light-emitting element 1 are thus emitted from the first upper surface. The wavelength of a portion of light from the light-emitting element 1 entering the second layer 12 through the lower surface of the second layer is converted by the second phosphor particles contained in the second layer to provide second converted light, and another portion of the light of the light-emitting element 1 is emitted from the second upper surface without being converted. At this time, in the second layer 12, the second converted light and the light not converted by the second phosphor particles are scattered by the light-reflective particles contained in the second layer 12. The scattering of light in the second layer can reduce the amount of light emitted from the second upper surface, so that it is possible to reduce the luminance of the second upper surface, that is, the luminance of the second light-emitting region R2. For example, a portion of light scattered by the light-reflective particles enters the first layer 11 and is emitted from the first upper surface of the first layer 11. The amount of light emitted from the first upper surface can thus be increased, and the luminance of the first light-emitting region R1 can be increased. Accordingly, in the light-emitting device 100, the first light-emitting region R1 can serve as a high-luminance region, and the second light-emitting region R2 can serve as a low-luminance region that emits light of a lower luminance than the luminance of the first light-emitting region R1.

In the case in which the light-emitting device 100 having the emission surface including the first light-emitting region R1 and the second light-emitting region R2 whose luminances are different as described above is used for a vehicle headlight, the high-luminance region can be located in a desired region in the irradiated region. A desired light distribution can therefore be easily obtained without a complicated optical design using a reflector, a lens, or the like. The size of headlight can thus be reduced, and the design qualities of the headlight can be enhanced.

The first phosphor particles in the first layer 11 and the second phosphor particles in the second layer 12 preferably contain the same phosphor material. This structure allows the first converted light and the second converted light to have the same peak emission wavelength and allows the first upper surface of the first layer 11 and the second upper surface of the second layer 12 to emit light of the same color. Even in the case in which the first phosphor particles and the second phosphor particles contain the same phosphor material, adjustment of the contents of the phosphor material in the respective layers allows light of different colors to be emitted from the first upper surface of the first layer 11 and the second upper surface of the second layer 12. The first phosphor particles in the first layer 11 and the second phosphor particles in the second layer 12 may contain different phosphor materials, which easily allows light of different colors to be emitted from the first upper surface of the first layer 11 and the second upper surface of the second layer 12.

In the wavelength conversion layer 10, the first layer 11 and the second layer 12 may be in contact with or separated from each other. In the wavelength conversion layer 10, the first layer 11 and the second layer 12 are preferably in contact with each other.

In the wavelength conversion layer 10, if the first layer 11 and the second layer 12 are in contact with each other, the first light-emitting region R1 and the second light-emitting region R2 having different luminances and/or chromaticities can be adjacent to each other in the light-emitting region R of the light-emitting device 100.

In this case, by causing the interface between the first layer 11 and the second layer 12 to be a surface substantially perpendicular to the upper surface of the wavelength conversion layer 10, the difference in luminance in the vicinity of the boundary between the first layer 11 and the second layer 12 between light emitted from the first upper surface and light emitted from the second upper surface can be increased. In other words, it is possible to let the luminance abruptly change in the vicinity of the boundary between the first layer 11 and the second layer 12.

As shown in FIG. 3B, in the case in which the first layer 11 and the second layer 12 are in contact with each other in the wavelength conversion layer 10, an abrupt change in luminance in the vicinity of the boundary thereof can be reduced by causing the boundary between the first layer 11 and the second layer 12 to be inclined with respect to the upper surface of the wavelength conversion layer 10.

That is, by appropriately adjusting the structure in the vicinity of the boundary between the first layer 11 and the second layer 12 according to the product specifications, the change in luminance in the vicinity of the boundary can be set. The inclined boundary between the first layer 11 and the second layer 12 can be curved as shown in FIG. 3B, or can be a flat surface.

As described above, the wavelength conversion layer 10 includes the first layer 11 containing the first phosphor particles and the second layer 12 containing the second phosphor particles and the light-reflective particles, so that the light-emitting device of the first embodiment can emit lights of different luminances from the first light-emitting region R1 and the second light-emitting region R2.

Further, the light-emitting device of the first embodiment can emit lights of the same color or different colors from the first light-emitting region R1 and the second light-emitting region R2 because the wavelength conversion layer 10 includes the first layer 11 containing the first phosphor particles and the second layer 12 containing the second phosphor particles and the light-reflective particles.

Configurations of the light-emitting device 1 of the first embodiment will be specifically described below.

### Light-Emitting Element 1

The light-emitting element 1 has the light exit surface 1a, a lower surface opposite to the light exit surface 1a, and lateral surfaces continuous with the light exit surface 1a and the lower surface. For the light-emitting element 1, a light-emitting diode can be used. The light-emitting element 1 includes a semiconductor structure body L1 and at least a pair of positive and negative element electrodes 1e. In the present specification, the term “element electrode 1e” is used in the case in which distinction between the positive and the negative is not especially required for the descriptions. In the case in which distinction between the positive and the negative is required, for example, the terms “p-electrode” and “n-electrode” are used. The semiconductor structure body L1 includes an n-side semiconductor layer, a p-side semiconductor layer, and an active layer interposed between the n-side semiconductor layer and the p-side semiconductor layer and, for example, is disposed on a supporting substrate S1. The active layer may have a single quantum well (SQW) structure or a multiple quantum well (MQW) structure including a plurality of well layers. For example, the semiconductor structure body includes a plurality of semiconductor layers formed of a nitride semiconductor. The nitride semiconductor includes semiconductors of any compositions in which composition ratios x and y in the chemical formula InₓAl_{y}Ga_{1-x-y}N (0≤x, 0≤y, and x+y≤1) vary in corresponding ranges. The peak emission wavelength of the active layer can be appropriately selected according to the purpose. For example, the active layer is configured to be able to emit visible light or ultraviolet light.

An example in which the semiconductor structure body includes a single light-emitting portion including the n-side semiconductor layer, the active layer, and the p-side semiconductor layer is described in the first embodiment, but as described referring to the following embodiments, a plurality of light-emitting portions each including the n-side semiconductor layer, the active layer, and the p-side semiconductor layer may be included. The expression “same peak emission wavelength” as used herein includes the case in which there are variations of approximately several nanometers. The combination of peak emission wavelengths of a plurality of light-emitting portions can be appropriately selected. In the case in which the semiconductor structure body includes two light-emitting portions, examples of the combination of lights emitted from the respective light-emitting portions include blue light and blue light, green light and green light, red light and red light, ultraviolet light and ultraviolet light, blue light and green light, blue light and red light, and green light and red light. In the case in which the semiconductor structure body includes three light-emitting portions, examples of the combination of lights emitted from the respective light-emitting portions include a combination of blue light, green light, and red light. At least one of the light-emitting portions may include one or more well layers having a peak emission wavelength different from the peak emission wavelength of the other well layers. The shape, size, and the like of the light-emitting element 1 can be variously selected according to the purpose.

The light-emitting element 1 may include the supporting substrate S1 for supporting the semiconductor structure body L1. Examples of the supporting substrate S1 include insulating substrates formed of sapphire, spinel (MgAl₂O₄), or the like and nitride semiconductor substrates formed of InN, AlN, GaN, InGaN, AlGaN, InGaAlN, or the like. In the case in which light emitted from the light-emitting portion is extracted through the supporting substrate (that is, in the case in which the supporting substrate constitutes the light exit surface 1a), the supporting substrate is preferably formed of a light-transmissive material.

The light-emitting element 1 includes an element electrode provided at least on the lower surface of the light-emitting element. For example, the pair of positive and negative element electrodes are provided on the same surface side of the semiconductor structure body. The positive and negative element electrodes can be arranged in consideration of the position of the wiring of the wiring board 40 and the like. For example, the element electrodes of the light-emitting element 1 are connected to the wiring of the wiring board 40 via electroconductive bonding members. For the electroconductive bonding members, eutectic solder, electroconductive paste of metal or the like, bumps, or the like can be used. The element electrodes of the light-emitting element 1 may be connected to the wiring by direct bonding without electroconductive members.

### Wavelength Conversion Layer 10

As described above, the wavelength conversion layer 10 includes the first layer 11 containing the first phosphor particles and the second layer 12 containing the second phosphor particles and the light-reflective particles. The wavelength conversion layer 10 has the upper surface and the lower surface, the upper surface of the wavelength conversion layer includes the upper surface of the first layer 11 and the upper surface of the second layer 12, and the lower surface of the wavelength conversion layer 10 includes the lower surface of the first layer 11 and the lower surface of the second layer 12. In other words, the wavelength conversion layer 10 includes the first layer 11 containing the first phosphor particles and the second layer 12 that contains the second phosphor particles and the light-reflective particles and is adjacent to the first layer. The first phosphor particles and the second phosphor particles in the first layer 11 and the second layer 12 convert wavelengths of at least a portion of light emitted from the light-emitting element 1 into other wavelengths.

For example, for the wavelength conversion layer 10, using a light-transmissive material such as a resin, glass, and an inorganic substance as a binder, a formed mixture of a phosphor as the first phosphor particles and the light-transmissive material for the first layer 11 and a formed mixture of a phosphor as the second phosphor particles, a light-reflective member as the light-reflective particles, and the light-transmissive material for the second layer can be used. Examples of the light-transmissive material include organic resin materials such as epoxy resins, silicone resins, phenolic resins, and polyimide resins and inorganic materials such as glass and ceramics.

In the wavelength conversion layer 10, the first phosphor particles in the first layer may be dispersed or concentrated in a certain portion. For example, in the first layer, the first phosphor particles may be concentrated on the lower surface side (that is, the light-emitting element side of the light-emitting device 100). Similarly, the second phosphor particles and the light-reflective particles in the second layer may be dispersed or concentrated. For example, in the second layer, the second phosphor particles may be concentrated on the lower surface side (that is, the light-emitting element side of the light-emitting device 100), and the light-reflective particles may be concentrated on the upper surface side (that is, the emission surface side of the light-emitting device 100).

Examples of the phosphor include yttrium-aluminum-garnet based phosphors (such as (Y,Gd)₃(Al,Ga)₅O₁₂:Ce), lutetium-aluminum-garnet based phosphors (such as Lu₃(Al,Ga)₅O₁₂:Ce), terbium-aluminum-garnet based phosphors (such as Tb₃(Al,Ga)₅O₁₂:Ce), CCA based phosphors (such as Ca₁₀(PO₄)₆Cl₂:Eu), SAE based phosphors (such as Sr₄Al₁₄O₂₅:Eu), chlorosilicate based phosphors (such as CasMgSi₄O₁₆Cl₂:Eu), silicate based phosphors (such as (Ba,Sr,Ca,Mg)₂SiO₄:Eu), oxynitride based phosphors such as β-SiAlON based phosphors (such as (Si,Al)₃(O,N)₄:Eu) and α-SiAlON based phosphors (such as Ca(Si,Al)₁₂(O,N)₁₆:Eu), nitride based phosphors such as LSN based phosphors (such as (La,Y)₃Si₆N₁₁:Ce), BSESN based phosphors (such as (Ba,Sr)₂Si₅N₈:Eu), SLA based phosphors (such as SrLiAl₃N₄:Eu), CASN based phosphors (such as CaAlSiN₃:Eu), and SCASN based phosphors (such as (Sr,Ca)AlSiN₃:Eu), fluoride based phosphors such as KSF based phosphors (such as K₂SiF₆:Mn), KSAF based phosphors (such as K₂(Si₁₋ₓAlₓ)F₆₋ₓ:Mn, where x satisfies 0<x<1), and MGF based phosphors (such as 3.5MgO·0.5MgF₂·GeO₂:Mn), quantum dots having the perovskite structure (such as (Cs,FA,MA)(Pb,Sn)(F,Cl,Br,I)₃, where FA and MA respectively represent formamidinium and methylammonium), group II-VI quantum dots (such as CdSe), group III-V quantum dots (such as InP), and quantum dots having the chalcopyrite structure (such as (Ag,Cu)(In,Ga)(S,Se)₂).

Examples of a light-reflective substance include titanium oxide, silicon oxide, zirconium oxide, aluminum oxide, magnesium oxide, calcium carbonate, calcium hydroxide, calcium silicate, zinc oxide, barium titanate, potassium titanate, aluminum nitride, boron nitride, mullite, and combinations thereof. Among these substances, titanium oxide is preferable because of the relatively high stability against water or the like and the high refractive index.

For example, the first phosphor particles and the second phosphor particles can be appropriately selected from the phosphors described above as examples according to the required product specifications of the light-emitting device 100.

For example, as a phosphor that emits yellow light to provide light having a white mixed color in combination with a blue light-emitting element, an yttrium-aluminum-garnet based phosphor in which a part of Y is substituted with Gd (such as (Y,Gd)₃Al₅O₁₂:Ce) can be preferably used. In the case in which the light-emitting device 100 that can emit white light is to be provided, the type and concentration of first phosphor particles contained in the first layer 11 are adjusted such that white light with a desired color temperature is emitted from the first layer 11 at a desired intensity, and the types and concentrations of second phosphor particles and the light-reflective particles contained in the second layer 12 are adjusted such that white light with a desired color temperature is emitted from the second layer 12 at a desired intensity.

An example of a structure will be described below in which the wavelength conversion layer 10 is disposed on or above a surface of the light-transmissive member 15 such as a glass plate serving as a support. The wavelength conversion layer 10 can be disposed on or above the light-transmissive member 15 by potting, printing, spraying, or the like. In the case in which the wavelength conversion layer 10 contains a resin, the first layer 11 and the second layer 12 can be easily disposed with predetermined thicknesses adjacently to each other because the light-transmissive member 15 supports the wavelength conversion layer 10 (that is, the first layer 11 and the second layer 12). The thickness of the first layer 11 and the thickness of the second layer 12 (that is, the shortest length from the upper surface to the lower surface in each of the first layer 11 and the second layer 12) in the wavelength conversion layer 10 are preferably the same. The thickness as the single wavelength conversion layer 10 thus becomes substantially uniform, and the wavelength conversion layer 10 on or above the light-emitting element 1 is easily disposed in the manufacturing process. The thickness of the wavelength conversion layer 10 is set in consideration of the relationships with the type and concentration of the first phosphor particles, the type and concentration of the second phosphor particles, and the type and concentration of the light-reflective particles such that the first layer 11 and the second layer 12 respectively emit light of predetermined chromaticities at predetermined intensities. For example, the thickness of the wavelength conversion layer 10 is set to 20 μm or more and 300 μm or less, preferably 50 μm or more and 150 μm or less, in consideration of size reduction in the light-emitting device 100 and the mechanical strength of the wavelength conversion layer 10.

### Light-Transmissive Member 15

Examples of the light-transmissive member 15 include a light-transmissive material such as a resin, glass, and an inorganic substance formed into a plate. The light-transmissive member 15 has an equal size to the size of the wavelength conversion layer 10 in a plan view and is disposed such that the lower surface is in contact with the upper surface of the wavelength conversion layer 10. The term “equal size” as used herein indicates that the difference in area between the lower surface of the light-transmissive member 15 and the upper surface of the wavelength conversion layer 10 is in ±5% of one or the other of the lower surface and the upper surface. For example, borosilicate glass, quartz glass, or the like can be used for the glass, and a silicone resin, an epoxy resin, or the like can be used for the resin. Among these materials, glass is preferably used for the light-transmissive member 15 in consideration of less tendency to be deteriorated due to light, the mechanical strength, and the like. The light-transmissive member 15 may contain a light-diffusing member. When the light-transmissive member 15 contains the light-diffusing member, variations in chromaticity and luminance can be reduced. Examples of the light-diffusing member include titanium oxide, barium titanate, aluminum oxide, and silicon oxide.

The light-transmissive member 15 can be disposed on or above the wavelength conversion layer 10 through other member(s) such as adhesive layer(s). The light-transmissive member 15 can be disposed on or above the wavelength conversion layer 10 through optical layer(s) such as dielectric multi-layer(s). An example of the dielectric multi-layer is a DBR (Distributed Bragg Reflector).

### Wiring Board 40

The wiring board 40 is a plate-shaped member including a base member 41 and wiring 42 on the upper surface of the base member 41.

For example, the base member 41 can be constituted of an insulating material such as glass epoxy, a resin, and a ceramic, a semiconductor material such as silicon, or an electroconductive material such as a metal. Among these materials, a ceramic, which is resistant to heat and light, can be preferably used. Examples of the ceramic include aluminum oxide, aluminum nitride, silicon nitride, and LTCC. A composite material of any of these insulating materials, semiconductor materials, and electroconductive materials can also be used. In the case in which a semiconductor material or an electroconductive material such as a metal is used for the base member 41, the wiring 42 can be provided on the upper surface and the lower surface of the base member 41 with insulating layers interposed therebetween.

The wiring 42 includes at least first wiring 421 and second wiring 422 provided on the upper surface of the base member 41. The wiring 42 may further include an external connection terminal provided on the lower surface opposite to the upper surface. In this case, for example, the first wiring 421 and the second wiring 422 provided on the upper surface of the base member 41 may be connected to the external connection terminal via relay wiring provided inside the base member 41 or on a lateral surface of the base member 41. Examples of the material of the wiring 42 include metals such as Fe, Cu, Ni, Al, Ag, Au, Pt, Ti, W, and Pd and alloys containing at least one of these metals.

### Electronic Component 30

For example, an electronic component 30 is a protective element. Examples of the protective element include a Zener diode. The electronic component 30 is connected to the first wiring 421 and the second wiring 422 via, for example, electroconductive members. The light-emitting device 100 may not include the electronic component 30.

### Covering Member 60

On the wiring board 40, the covering member 60 covers the lateral surfaces of the light-transmissive member 15, the lateral surfaces of the wavelength conversion layer 10, and the lateral surfaces of the light-emitting element 1 such that the upper surface of the light-transmissive member 15 is exposed. In the case in which the light-emitting device 100 includes the electronic component 30, the covering member 60 preferably covers the electronic component 30.

The covering member 60 preferably has light-shielding properties (specifically light-reflective properties and/or light-absorbing properties), particularly preferably light-reflective properties. An insulating material is preferably used for the covering member 60. For example, a thermosetting resin, a thermoplastic resin, or the like can be used for the covering member 60. Specific examples of the covering member 60 include a resin containing particles of a light-reflective substance. Examples of the resin include a resin containing at least one of a silicone resin, a modified silicone resin, an epoxy resin, a modified epoxy resin, an acrylic resin, a phenolic resin, a bismaleimide-triazine resin, and a polyphthalamide resin, or hybrid resin thereof. Among these materials, a resin containing a silicone resin, which has good heat resistance, electrical insulating properties, and flexibility, as a base polymer is preferable. For the light-reflective substance, a material selected from the materials in the wavelength conversion layer 10 mentioned above as examples can be used. The covering member 60 can further contain particles of a light-absorbing substance such as a pigment, carbon black, titanium black, and graphite. In the light-reflective and/or light-absorbing covering member 60, particles of a light-reflective substance and/or a light-absorbing substance are preferably dispersed in the resin.

For example, the concentration of the light-reflective substance in the covering member 60 is preferably 60 mass % or more and 70 mass % or less. The concentration of the light-reflective substance refers to the proportion of the light-reflective substance in the covering member 60 including the light-reflective substance. For example, the reflectance of the covering member 60 is preferably 70% or more, more preferably 80% or more. The reflectance refers to a reflectance at a peak emission wavelength of light emitted from the light-emitting element 1.

A method of manufacturing the light-emitting device of the first embodiment will be described below.

The method of manufacturing the light-emitting device of the first embodiment includes:
(1) a step ST1 of providing the light-emitting element 1,
(2) a step ST2 of providing a collective substrate,
(3) a step ST3 of providing the wavelength conversion layer 10,
(4) a step ST4 of disposing the light-emitting element 1,
(5) a step ST5 of disposing the wavelength conversion layer 10,
(6) a step ST6 of disposing the covering member, and
(7) a step ST7 of performing singulation into each light-emitting device.

The step ST3 of providing the wavelength conversion layer 10 includes:
a step ST31 of providing a first resin and a second resin,
a step ST32 of disposing the first layer on or above the light-transmissive member,
a step ST33 of disposing the second layer on or above the light-transmissive member, and
a step ST34 of performing singulation into each wavelength conversion layer 10.

Each of these steps will be described below.

### (1) Step ST1 of Providing Light-Emitting Element 1

In the step ST1 of providing the light-emitting element 1, the light-emitting element 1 including the supporting substrate, the semiconductor structure body including at least one light-emitting portion, and at least a pair of positive and negative element electrodes is provided. Specifically, in the light-emitting element 1, the semiconductor structure body is located on the supporting substrate, and at least a pair of positive and negative element electrodes are provided on the surface opposite to the supporting substrate side of the semiconductor structure body. The light exit surface of the light-emitting element is the surface on the supporting substrate side, and the wavelength conversion layer described below is disposed on or above the supporting substrate. The light-emitting element 1 can be provided through part or the whole of the manufacturing process, such as through a step such as growing a semiconductor. Alternatively, the light-emitting element 1 may be provided by purchasing, transfer, or the like.

### (2) Step ST2 of Providing Collective Substrate

In the step ST2 of providing the collective substrate, the collective substrate including a plurality of substrate regions intended to be the wiring boards of the light-emitting devices 100 is provided. For example, the substrate regions are arranged in a matrix. For example, the collective substrate is provided by firstly providing a plate-shaped base member (that is, a collective body of the base member 41) formed of glass epoxy, a resin, or a ceramic. Subsequently, the first wirings and the second wirings are formed in the substrate regions of the base member. The first wiring and the second wiring can be formed by a known method such as plating, vapor deposition, and sputtering. A collective substrate provided with the wiring in advance may be provided by purchasing, transfer, or the like.

### (3) Step ST3 of Providing Wavelength Conversion Layer 10

In the step ST3 of providing the wavelength conversion layer 10, the wavelength conversion layer including the first layer using the first resin and the second layer using the second resin is provided. In this example, a wavelength conversion layer 10 disposed on or above the light-transmissive member is provided as the wavelength conversion layer 10.

For example, as described above, the step ST3 of providing the wavelength conversion layer 10 includes the step ST31 of providing the first resin and the second resin, the step ST32 of disposing the first layer on or above the light-transmissive member, the step ST33 of disposing the second layer on or above the light-transmissive member, and the step ST34 of performing singulation into each wavelength conversion layer.

In the step ST31 of providing the first resin and the second resin, the first resin containing the first phosphor particles and the second resin containing the second phosphor particles and the light-reflective particles are provided.

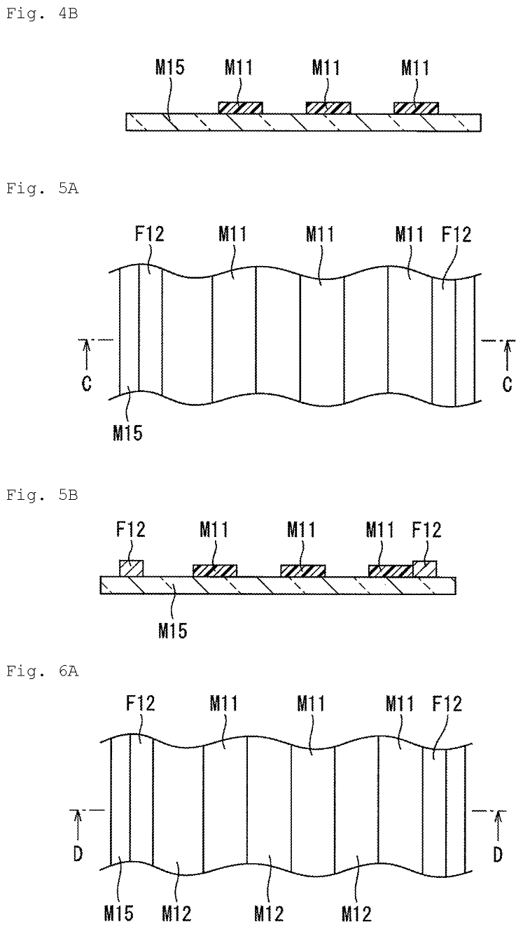

In the step ST32 of disposing the first layer on or above the light-transmissive member, as shown in FIG. 4A and FIG. 4B, first layers M11 are formed into, for example, a striped pattern on or above a flat plate-shaped light-transmissive member M15. The light-transmissive member M15 refers to a collective body including a plurality of regions intended to be the light-transmissive members 15 of the individual light-emitting devices 100 after singulation. The first layers M11 include first layers 11 that constitute the wavelength conversion layers of the individual light-emitting devices 100 after singulation. The same applies to a second layer M12. The example in which the first layers M11 are formed into a striped pattern has been described here, but the pattern is not limited to a striped pattern but can be a grid-like or island-like pattern. For example, the first layer can be formed on or above the light-transmissive member M15 by printing using a mask.

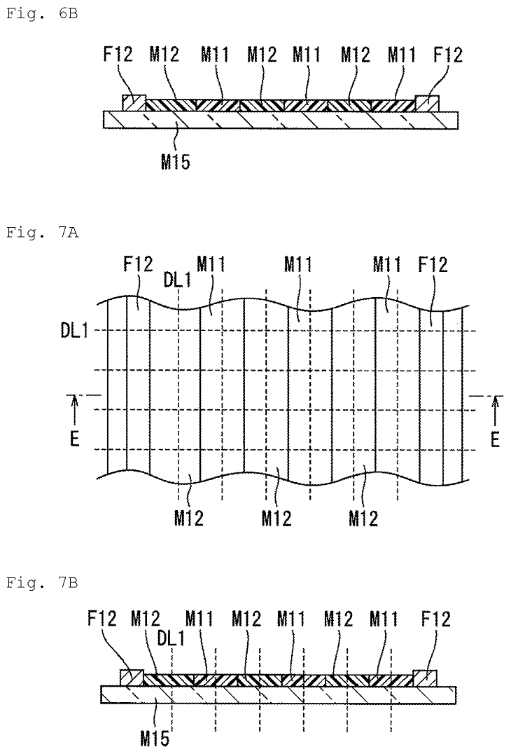

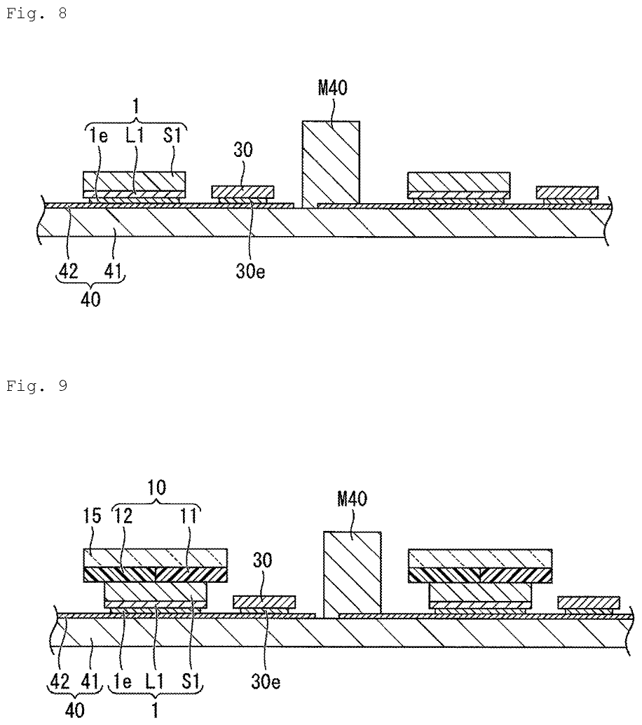

In the step ST33 of disposing the second layers on or above the light-transmissive member, for example, similarly to the step S32 of forming the first layers described above, the second layers M12 are formed into a striped pattern in the gaps of the first layers M11 by printing using a mask. This step is also not limited to printing, and for example, after a frame F12 surrounding the first layers M11 is formed on or above the light-transmissive member M15 as shown in FIG. 5A and FIG. 5B, the second layers M12 can be formed in the gaps of the first layers M11 by potting or the like as shown in FIG. 6A and FIG. 6B. The second layers M12 can be formed into islands.

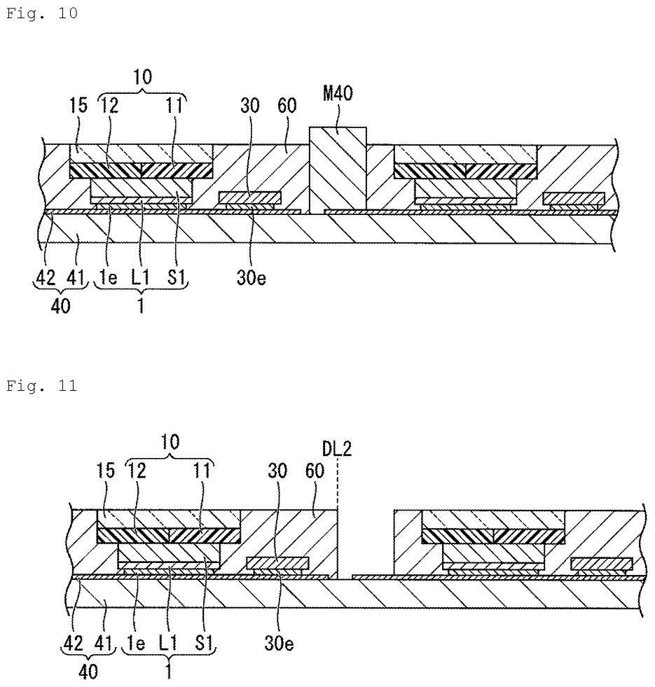

Subsequently, in the step ST34 of performing singulation into each wavelength conversion layer 10, as shown in FIG. 7A and FIG. 7B, the first layer M11, the second layer M12, and the light-transmissive member 15 are divided such that the wavelength conversion layer 10 after singulation includes the first layer 11 and the second layer 12 (for example, along dividing lines indicated by broken lines DL1 in FIG. 7B) to provide the wavelength conversion layers 10 disposed on or above the light-transmissive members 15.

Through the above steps, the wavelength conversion layers 10 which are disposed on or above the light-transmissive members 15 and each of which includes the first layer 11 and the second layer 12 are provided.

### (4) Step ST4 of Disposing Light-Emitting Element 1

In the step ST4 of disposing the light-emitting element 1, the light-emitting elements 1 are disposed on the substrate regions of the collective substrate. For example, the arrangement of the light-emitting elements 1 is as shown in FIG. 8, in which the light-emitting element 1 is disposed at a predetermined position in each substrate region such that the element electrodes 1e face the wiring 42. For example, the wiring 42 and the element electrodes 1e are bonded together with the electroconductive bonding members. When necessary, the electronic components 30 are also disposed at predetermined positions.

The member denoted by the reference numeral M40 in FIG. 8 and other drawings is a mask provided to expose the wiring 42 from the covering member 60.

### (5) Step ST5 of Disposing Wavelength Conversion Layer 10

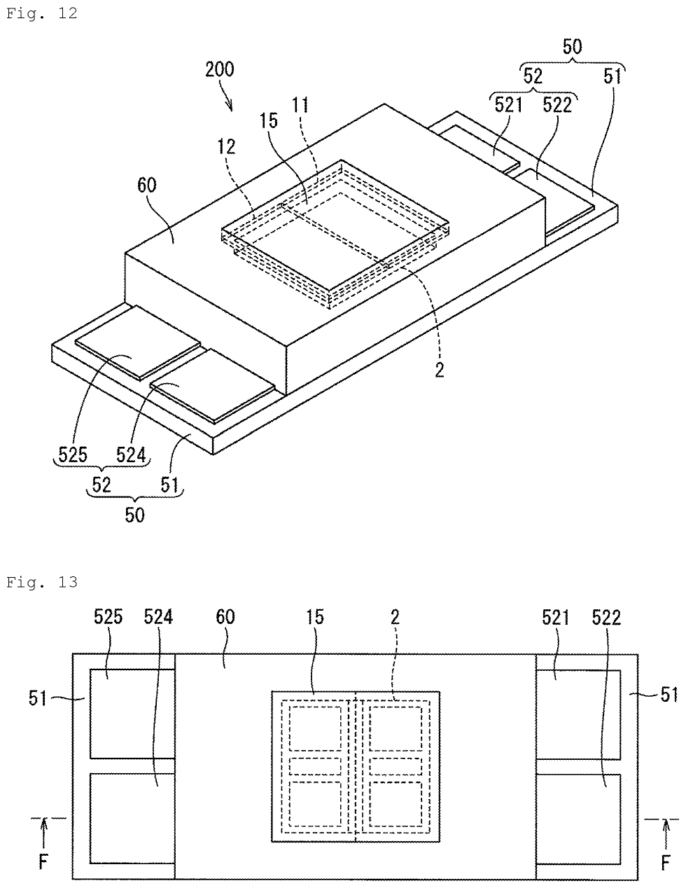

In the step ST5 of disposing the wavelength conversion layer 10, as shown in FIG. 9, the wavelength conversion layers 10 are disposed to respectively face the light exit surfaces of the light-emitting elements 1 disposed on the collective substrate. For example, the light-emitting elements 1 and the wavelength conversion layers 10 are bonded together with light-transmissive bonding members or the like. In the example described here, the wavelength conversion layers 10 with the light-transmissive members 15 are disposed, but the wavelength conversion layers 10 alone can be disposed on or above the light-emitting elements 1. Alternatively, after the wavelength conversion layers 10 are disposed together with the light-transmissive members 15, the light-transmissive members 15 can be removed. An example in which the light-emitting device includes the light-transmissive member 15 will be described below.

### (6) Step ST6 of Disposing Covering Member

In the step ST6 of disposing the covering member, as shown in FIG. 10, the covering member 60 is disposed to cover the lateral surfaces of the light-emitting elements 1, the lateral surfaces of the wavelength conversion layers 10, and the lateral surfaces of the light-transmissive members 15 disposed on or above the collective substrate such that the upper surfaces of the light-transmissive members 15 intended to constitute the emission surfaces of the light-emitting devices are exposed. For example, the covering member 60 is disposed by applying an uncured resin containing the light-reflective substance to cover the lateral surfaces of the light-emitting elements 1, the lateral surfaces of the wavelength conversion layers 10, and the lateral surfaces of the light-transmissive members 15 and then curing the resin. For example, the upper surfaces of the light-transmissive members 15 can be exposed from the covering member by applying the uncured resin to regions excluding the upper surfaces of the light-transmissive members 15.

After the covering member 60 is disposed (cured), as shown in FIG. 11, the mask M40 is removed. The mask M40 can be removed after singulation described below.

In the step of disposing the covering member, a wall for retaining the covering member may be disposed on the collective substrate without using the mask M40. For example, a resin having hardness higher than the hardness of the resin constituting the covering member can be used for the wall. The wall can be a portion of the base member, and for example, the wiring board can have a structure having recesses in which the light-emitting elements are disposed.

### (7) Step of Performing Singulation into Each Light-Emitting Device

In the step of performing singulation into each light-emitting device, the collective substrate is divided along the outer edges (for example, dividing lines indicated by broken lines DL2 in FIG. 11) of individual substrate regions into individual light-emitting devices 100 with a blade or the like.

The light-emitting device 100 of the first embodiment is produced through the above steps.

In the method of manufacturing the light-emitting device 100 of the first embodiment, the chromaticity and emission spectrum of light emitted from the upper surface of the first layer 11, the chromaticity and emission spectrum of light emitted from the upper surface of the second layer 12, the luminance in the first light-emitting region R1, and the luminance in the second light-emitting region R2 are set by selecting the type of the light-emitting element 1, respectively selecting suitable materials for the material of the wavelength conversion layer and the like, and appropriately setting various parameters such as the thickness of the wavelength conversion layer.

Examples of selections of the materials and settings of related parameters in the method of manufacturing the light-emitting device 100 of the first embodiment will be described below.

In the method of manufacturing the light-emitting device 100 of the first embodiment, the light-emitting element 1 and the materials for the first phosphor particles and the second phosphor particles are selected such that the first light-emitting region R1 and the second light-emitting region R2 of the light-emitting device 100 respectively emit light of predetermined emission spectra.

For example, in the case in which the first light-emitting region R1 and the second light-emitting region R2 emit light of the same emission spectrum, for example, the same material is preferably selected for the first phosphor particles and the second phosphor particles. Even in the case in which the same material is selected for the first phosphor particles and the second phosphor particles, emission spectra of light emitted is affected by the contents of the phosphor particles in the first layer 11 and the second layer 12 and the like, but the contents of the phosphor particles in the first layer 11 and the second layer 12 and the like can be relatively easily set as compared with the case in which different materials are selected for the first phosphor particles and the second phosphor particles. As will be understood from the above description, even in the case in which the same material is selected for the first phosphor particles and the second phosphor particles, it is possible to make the emission spectrum of light emitted from the first light-emitting region R1 different from the emission spectrum of light emitted from the second light-emitting region R2 by appropriately adjusting the contents of the phosphor particles in the first layer 11 and the second layer 12 and the like.

In the method of manufacturing the light-emitting device 100 of the first embodiment, in order to set the luminance of the upper surface of the first layer 11 and the luminance of the upper surface of the second layer 12 to respective predetermined luminances, for example, the content of the first phosphor particles in the first resin, the contents of the second phosphor particles and the light-reflective particles in the second resin, the thickness of the first layer 11 and the thickness of the second layer 12, and the like are set so that the luminance of the upper surface of the first layer 11 and the luminance of the upper surface of the second layer 12 will be respective predetermined luminances.

For example, in the case in which the same phosphor material constitutes the first phosphor particles and the second phosphor particles, appropriately adjusting the content of the first phosphor particles in the first layer, the contents of the second phosphor particles and the light-reflective particles in the second layer, and the type(s) of the light-reflective particles in the second layer allows the first light-emitting region R1 and the second light-emitting region R2 to emit light at different luminances. For example, when the content of the light-reflective particles in the second layer 12 is increased, a larger portion of light that has been subjected to wavelength conversion by the second layer 12 and light entering the second layer 12 from the light-emitting element is scattered, so that the amount of light exiting from the second upper surface can be reduced. The light scattered by the second layer 12 enters the first layer 11, which increases the amount of light emitted from the first upper surface of the first layer 11, so that the amount of light exiting from the first upper surface can be increased.

Alternatively, the arrangements of the first phosphor particles in the first layer 11 and the second phosphor particles and the light-reflective particles in the second layer 12 can be adjusted. For example, by concentrating the light-reflective particles on the upper surface side in the second layer 12, the ratio of entry into the first layer 11 of light that has been subjected to wavelength conversion by the second layer 12 and light entering the second layer 12 from the light-emitting element can be adjusted, so that the difference in luminance between the first light-emitting region R1 and the second light-emitting region R2 can be adjusted. Such adjustment of arrangement of each sort of particles in each layer can be achieved by appropriately adjusting the type and particle diameter of each sort of particles.

As described above, the method of manufacturing the light-emitting device 100 of the first embodiment can manufacture the light-emitting device that can emit light of predetermined emission colors at predetermined luminances respectively from the first light-emitting region R1 and the second light-emitting region R2 by appropriately selecting the type of the light-emitting element 1 and the phosphor materials and appropriately setting related parameters such as contents of the phosphor particles and the like and the thicknesses of the first layer 11 and the second layer 12. In the method of manufacturing the light-emitting device 100 of the first embodiment, the parameters in each step can also be set by using a database containing the relationships between (i) the type of the light-emitting element 1, the types of the phosphor materials, the contents of the phosphor particles and the like and the thicknesses of the first layer 11 and the second layer 12, and (ii) the emission colors and luminances of lights respectively emitted from the first light-emitting region R1 and the second light-emitting region R2.

### Second Embodiment

A light-emitting device 200 according to a second embodiment of the present disclosure differs from the light-emitting device 100 of the first embodiment in that a light-emitting element 2 includes a first light-emitting portion 21 and a second light-emitting portion 22, light emitted from the first light-emitting portion 21 enters the first layer 11 of the wavelength conversion layer 10, and light emitted from the second light-emitting portion 22 enters the second layer 12 of the wavelength conversion layer 10. This structure in which the light-emitting element 2 includes the first light-emitting portion 21 and the second light-emitting portion 22 also makes the wiring structure of the wiring board different.

The features of the light-emitting device 200 of the second embodiment different from the features of the light-emitting device 100 of the first embodiment will be mainly described below.

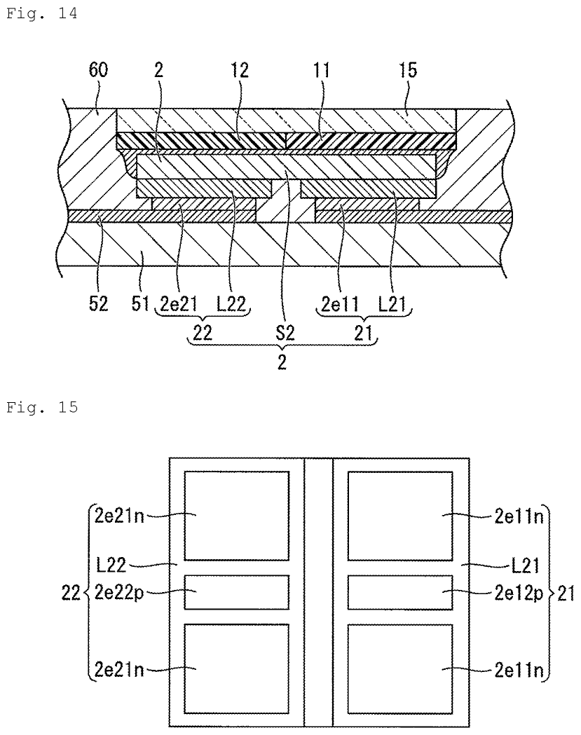

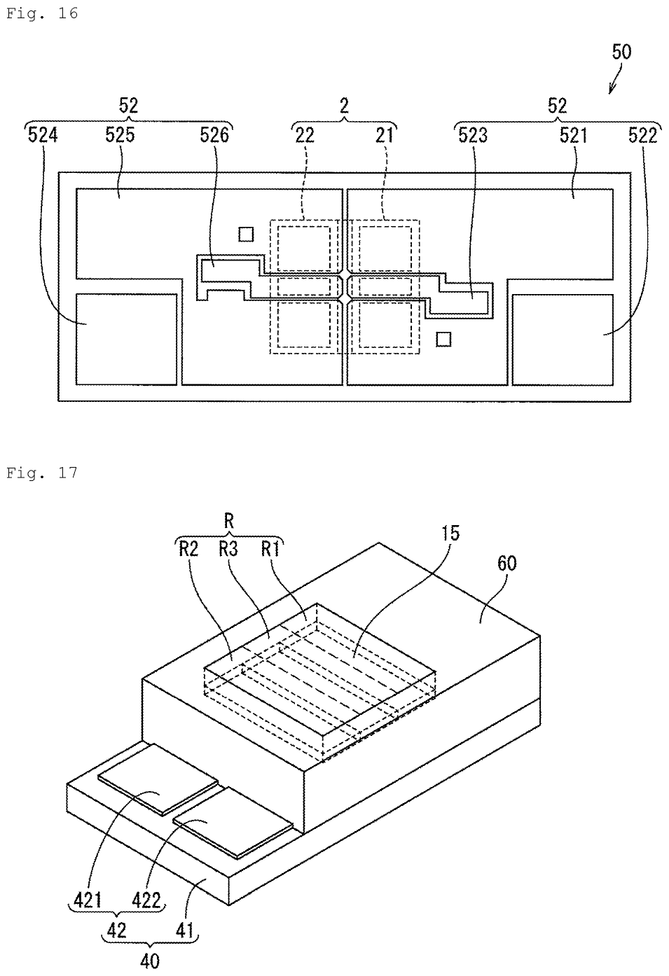

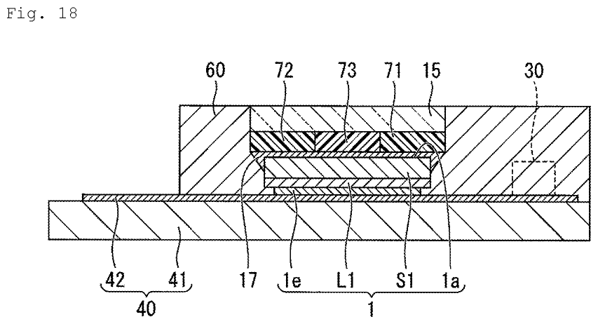

FIG. 12 is a schematic perspective view of the light-emitting device 200 according to the second embodiment. FIG. 13 is a schematic plan view of the light-emitting device according to the second embodiment from above. FIG. 14 is a schematic cross-sectional view taken along the line F-F of FIG. 13. FIG. 15 is a schematic plan view showing the electrode configuration of the light-emitting element 2, and FIG. 16 is a schematic plan view of the wiring of a wiring board 50.

In the light-emitting device 200 according to the second embodiment, the light-emitting element 2 includes the first light-emitting portion 21 and the second light-emitting portion 22 on a supporting substrate S2. The first light-emitting portion 21 includes a first semiconductor structure body L21 disposed on the supporting substrate S2 and an element electrode 2e11 disposed on the first semiconductor structure body L21. The second light-emitting portion 22 includes a second semiconductor structure body L22 disposed on the supporting substrate S2 and an element electrode 2e21 disposed on the second semiconductor structure body L22. For example, the first semiconductor structure body L21 and the second semiconductor structure body L22 are disposed on the supporting substrate S2 so as to be separated from each other.

For example, the first light-emitting portion and the second light-emitting portion, in other words, the first semiconductor structure body L21 and the second semiconductor structure body L22, can have the same semiconductor structure or different semiconductor structures. By providing the respective element electrodes separately on the first semiconductor structure body L21 and the second semiconductor structure body L22, individual turning on becomes possible. Further, by connecting the respective element electrodes of the first light-emitting portion and the second light-emitting portion in series, turning on at once becomes possible. Even in the case in which the first semiconductor structure body L21 and the second semiconductor structure body L22 emit light of the same color, by adjusting the phosphor materials and the contents of the first phosphor particles, the second phosphor particles, particles of the light-reflective material, and the like in the first layer 11 and the second layer 12 of the wavelength conversion layer 10, the first light-emitting region R1 and the second light-emitting region R2 can be caused to emit light of different colors.

In the light-emitting device 200 according to the second embodiment, for example, as shown in FIG. 15, the electrodes of the light-emitting element 2 can be provided such that, on the first semiconductor structure body L21 and the second semiconductor structure body L22, p-electrodes 2e12p and 2e22p are provided on the central portions, and n-electrodes 2e11n are provided on both sides of the p-electrodes 2e12p, and 2e21n are provided on both sides of 2e22p. FIG. 15 shows an example in which the first semiconductor structure body L21 and the second semiconductor structure body L22 are separated from each other, but the first semiconductor structure body L21 and the second semiconductor structure body L22 can have a structure in which the respective active layers are separated from each other but the p-side semiconductor layers or the n-side semiconductor layers are connected to each other.

In the light-emitting device 200 according to the second embodiment, for example, as shown in FIG. 16, wiring 52 in the wiring board 50 includes first wiring 521, second wiring 522, and third wiring 523 connected to the first light-emitting portion 21, and fourth wiring 524, fifth wiring 525, and sixth wiring 526 connected to the second light-emitting portion 22.

The third wiring 523 is located at a position facing the p-electrode 2e12p in the region in which the first light-emitting portion 21 is mounted. The first wiring 521 is located at positions facing the n-electrodes 2e11n of the first light-emitting portion 21; that is, the first wiring 521 includes internal connecting portions located on both sides of the third wiring 523 and a first external connecting portion extending from the mounting portion to an end portion. The second wiring 522 is adjacent to the first external connecting portion on one end portion of the wiring board. For example, the second wiring 522 and the third wiring 523 are connected via an electroconductive member such as a wire or relay wiring provided in the base member so that electrical connection to the first wiring 521 is not established.

The fourth wiring 524, the fifth wiring 525, and the sixth wiring 526 are provided in a manner similar to the first wiring 521, the second wiring 522, and the third wiring 523, respectively, in the region in which the second light-emitting portion 22 is mounted.

The example in which the first wiring 521 and the fourth wiring 524, and the third wiring 523 and the sixth wiring 526 are electrically separated from each other on the base member has been described above, but one of the pair of the first wiring 521 and the fourth wiring 524 and the pair of the third wiring 523 and the sixth wiring 526 may be electrically connected to each other.

On the wiring board 50 having the above structure, the light-emitting element 2 is mounted such that the p-electrode 2e12p of the first semiconductor structure body L21 is connected to the third wiring 523, the n-electrodes 2e11n are connected to the first wiring 521, the p-electrode 2e22p of the second semiconductor structure body L22 is connected to the sixth wiring 526, and the n-electrodes 2e21n are connected to the fourth wiring 524.

In the light-emitting device 200 of the second embodiment, the wavelength conversion layer is constituted in the same manner as in the light-emitting device 100 of the first embodiment, the first layer 11 is located above the first light-emitting portion 21 with the supporting substrate S2 interposed therebetween, and the second layer 12 is located above the second light-emitting portion 22 with the supporting substrate S2 interposed therebetween.

The light-emitting device 200 of the second embodiment having the above structure can emit light of different luminances from the first light-emitting region R1 and the second light-emitting region R2 because the wavelength conversion layer 10 includes the first layer 11 containing the first phosphor particles and the second layer 12 containing the second phosphor particles and the light-reflective particles.

Further, the light-emitting device 200 of the second embodiment in which the wavelength conversion layer 10 includes the first layer 11 containing the first phosphor particles and the second layer 12 containing the second phosphor particles and the light-reflective particles can emit light of the same color or different colors from the first light-emitting region R1 and the second light-emitting region R2 similarly to the light-emitting device 100 of the first embodiment.

In particular, the emission colors and emission intensities of the first light-emitting portion 21 and the second light-emitting portion 22 can be selected as desired in the light-emitting device 200 of the second embodiment. This structure can allow for easily increasing the difference in luminance and the difference in emission color between the first light-emitting region R1 and the second light-emitting region R2.

Further, the first light-emitting portion 21 and the second light-emitting portion 22 can be individually turned on, so that the luminance of the first light-emitting region R1 or the second light-emitting region R2 can be substantially zero.

Furthermore, the emission color and emission intensity of the first light-emitting portion 21 and the emission color and emission intensity of the second light-emitting portion 22 can be variously selected, so that a light-emitting device having a first region R1 and a second region R2 of desired emission colors and emission intensities can be provided.

### Third Embodiment

A light-emitting device 300 according to a third embodiment of the present disclosure differs from the light-emitting device 100 of the first embodiment in that a wavelength conversion layer 70 includes, in addition to a first layer 71 and a second layer 72, a third layer 73 between the first layer 71 and the second layer 72.

The third layer 73 contains third phosphor particles and light-reflective particles, and the concentration of the light-reflective particles in the third layer 73 is smaller than the concentration of light-reflective particles in the second layer 72.

The third phosphor particles contained in the third layer 73 can be the same as either the first phosphor particles or the second phosphor particles or can be different from these phosphor particles.

The light-reflective particles contained in the third layer 73 can be the same as or different from the light-reflective particles contained in the second layer 72.

Accordingly, the light-emitting device 300 can include a third light-emitting region R3 (medium-luminance region) between the first light-emitting region R1 (high-luminance region) and the second light-emitting region R2 (low-luminance region). In the light-emitting device 300, the luminance of the medium-luminance region is larger than the luminance of the low-luminance region and smaller than the luminance of the high-luminance region.

The light-emitting device 300 includes the medium-luminance region. This structure can allow the difference in luminance between the high-luminance region and the low-luminance region to be gentle.

The light-emitting devices according to the embodiments include aspects described above.

The light-emitting devices according to the embodiments of the present disclosure can be preferably used for lightings for vehicles such as headlights. In addition, the light-emitting devices according to the embodiments of the present disclosure can be used for backlight sources for liquid-crystal displays, various lighting apparatuses, large screen displays, and various display devices such as advertisements and information boards, as well as image scanners in digital video cameras, facsimile machines, copying machines, scanners, and the like, and projector devices, and the like.

What is claimed is:

1. A light-emitting device comprising:
a light-emitting element having a light exit surface;
a wavelength conversion layer having a lower surface and an upper surface opposite to the lower surface, the wavelength conversion layer being disposed on or above the light-emitting element so that the lower surface of the wavelength conversion layer faces the light exit surface of the light-emitting element, the wavelength conversion layer including
a first layer containing a first phosphor particle, and constituting a part of the upper surface and a part of the lower surface of the wavelength conversion layer, and
a second layer containing a second phosphor particle and a light-reflective particle, and constituting a part of the upper surface and a part of the lower surface of the wavelength conversion layer; and
a light-transmissive layer disposed on or above the wavelength conversion layer.

2. The light-emitting device according to claim 1, wherein a thickness of the first layer is the same as a thickness of the second layer.

3. The light-emitting device according to claim 1, wherein the first phosphor particle in the first layer and the second phosphor particle in the second layer include the same phosphor material.

4. The light-emitting device according to claim 1, wherein the first layer and the second layer are in contact with each other.

5. The light-emitting device according to claim 4, wherein a boundary between the first layer and the second layer in the wavelength conversion layer is inclined with respect to the upper surface of the wavelength conversion layer.

6. The light-emitting device according to claim 1, further comprising a covering member covering a lateral surface of the light-emitting element and a lateral surface of the wavelength conversion layer.

7. The light-emitting device according to claim 1, wherein the light-emitting element includes a supporting substrate and a plurality of light-emitting portions spaced apart from each other on the supporting substrate.

8. The light-emitting device according to claim 7, wherein a boundary between the first layer and the second layer is located between adjacent ones of the plurality of light-emitting portions in a plan view.

9. The light-emitting device according to claim 7, wherein the plurality of light-emitting portions are configured to be individually controlled.

10. The light-emitting device according to claim 1, wherein
the wavelength conversion layer further includes a third layer containing a third phosphor particle and a light-reflective particle, and
a concentration of the light-reflective particle in the third layer is smaller than a concentration of the light-reflective particle in the second layer.

11. The light-emitting device according to claim 10, wherein
the third layer constitutes a part of the upper surface and a part of the lower surface of the wavelength conversion layer.

12. The light-emitting device according to claim 1, further comprising a wiring board on which the light-emitting element is disposed.

13. The light-emitting device according to claim 1, further comprising a light-transmissive bonding member between the wavelength conversion layer and the light-emitting element.

14. The light-emitting device according to claim 1, wherein a thickness of the wavelength conversion layer is in a range of 20 μm or more and 300 μm or less.

15. The light-emitting device according to claim 1, wherein the light transmissive member is formed of glass.

16. The light-emitting device according to claim 1, wherein the wavelength conversion layer includes a resin.
